(19) United States
(12) Patent Application Publication
(10) Pub. No.: US 2008/0064219 A1
(43) Pub. Date: Mar. 13, 2008

(54) METHOD OF REMOVING PHOTORESIST

(76) Inventor: Chung-Kyung Jung, Gyeonggi-do (KR)

Correspondence Address: SHERR & NOURSE, PLLC, 620 HERNDON PARKWAY, SUITE 200, HERNDON, VA, 20170, US

(21) Appl. No.: 11/846,875

(22) Filed: Aug. 29, 2007

(30) Foreign Application Priority Data
Sep. 13, 2006 (KR) 10-2006-0088436

(51) Int. Cl. H01L 21/311

(52) U.S. Cl. 438/703; 257/E21.247

(57) ABSTRACT

A method of removing a photoresist in a semiconductor manufacturing process including at least one of the following steps: sequentially depositing an oxide film and a metal film over a semiconductor substrate. Depositing an anti-reflection film and a photoresist over the metal film. Patterning the photoresist to form a photoresist pattern. Prompting a surface reaction of the semiconductor substrate using a chuck to remove a polymer film formed on the surface of the photoresist pattern. Removing the photoresist pattern by a plasma etching process while spraying a photoresist removal gas containing fluorine to cause a reaction between aluminum and fluorine.

The present application claims priority under 35 U.S.C. 119 to Korean Patent Application No. 10-2006-0088436 (filed on Sep. 13, 2006), which is hereby incorporated by reference in its entirety.

### BACKGROUND

During the fabrication of semiconductor devices, a metal wiring layer is provided on and/or over a semiconductor substrate in order to form an electrode and as interconnects for linking semiconductor devices. The metal may be formed by forming an oxide film and a barrier metal on and/or over the surface of the semiconductor substrate. A metal film such as aluminum (Al) or an aluminum alloy is then deposited on and/or over the substrate. The aluminum metal wiring may contain 0.5 wt % of copper. Next, a photoresist is coated on and/or over the substrate, and subsequently patterning the photoresist using a photolithography process. The photoresist pattern may be used as a mask in order to etch the metal film layer. The photoresist is then removed after etching is performed.

Dry etching using boron chloride (BCl₃) may be used when etching the metal film. On or more polymers containing water (H₂O) and chlorine (Cl) particles may be produced during dry etching on the surface of the photoresist or the sidewall of the metal film. Such polymers are undesirable and make it difficult to remove the photoresist. The polymers may be removed in-situ by initiating a surface reaction on the semiconductor substrate using a high-temperature chuck in a photoresist removal chamber. The remaining photoresist pattern on the metal film layer may then be removed using a plasma etching process. Once the photoresist is removed, the polymer formed on the sidewall of the metal film may be etched using a wet etching method and is cleaned, thereby forming the metal wiring layer.

Unfortunately, the removal of the photoresist may result in undesirable effects. For example, once the photoresist pattern is removed, the metal wiring composed of aluminum (Al) is exposed to an aqueous solution, which condenses and separates the copper (Cu) from the wiring due to a standard reduction potential difference between aluminum (Al) and copper (Cu). The solution may then attack the exposed metal lines, i.e., causing metal attack.

### SUMMARY

In accordance with embodiments, a method of removing a photoresist during a semiconductor manufacturing process includes injecting fluorine (F) in order to reduce metal attack. Particularly, embodiments include a semiconductor manufacturing process including at least one of the following steps: sequentially depositing an oxide film and a metal film on and/or over a semiconductor substrate. Forming an anti-reflection film and a photoresist on and/or over the metal film. Patterning the photoresist to form a photoresist pattern. Prompting a surface reaction of the semiconductor substrate using a chuck thereby removing a polymer formed on the surface of the photoresist pattern. Removing the photoresist pattern using a plasma etching process while simultaneously spraying a photoresist removal gas containing fluorine (F).

### DRAWINGS

FIG. 1 illustrates a reaction mechanism due to a reduction potential difference between aluminum and copper.

FIGS. 2A to 2C illustrate a method of removing a photoresist during a semiconductor manufacturing process, in accordance with embodiments.

### DESCRIPTION

Example Table 1 illustrates standard reduction potentials of elements copper (Cu), aluminum (Al), and fluorine (F).

TABLE 1

| Standard reduction potential | | |
|---|---|---|
| (Cell) | Volts | Remark |
| Cu—Cu+2 | 0.337 | Noble |
| H2—H+ | 0.000 | Standard |
| Al—Al+3 | 1.662 | Active |
| F2—F− | 2.87 | Reduction |

As illustrated in example Table 1, because aluminum (Al), which may be used as a reducing agent, has a negative standard reduction potential, an oxidation reaction easily occurs causing aluminum to become oxidized into aluminum ions (Al+3). Since copper (Cu) is a weaker reducing agent than aluminum, a reduction reaction occurs. Accordingly, the copper ions are converted into solid copper that may be separated from the metal wiring, causing metal attack in the semiconductor device. In order to suppress or otherwise eliminate the metal attack, fluorine (F), which is a stronger oxidizing agent than copper, is injected in order to cause it to react with aluminum. This reaction reduces or otherwise eliminates metal attack during the process of removing the photoresist.

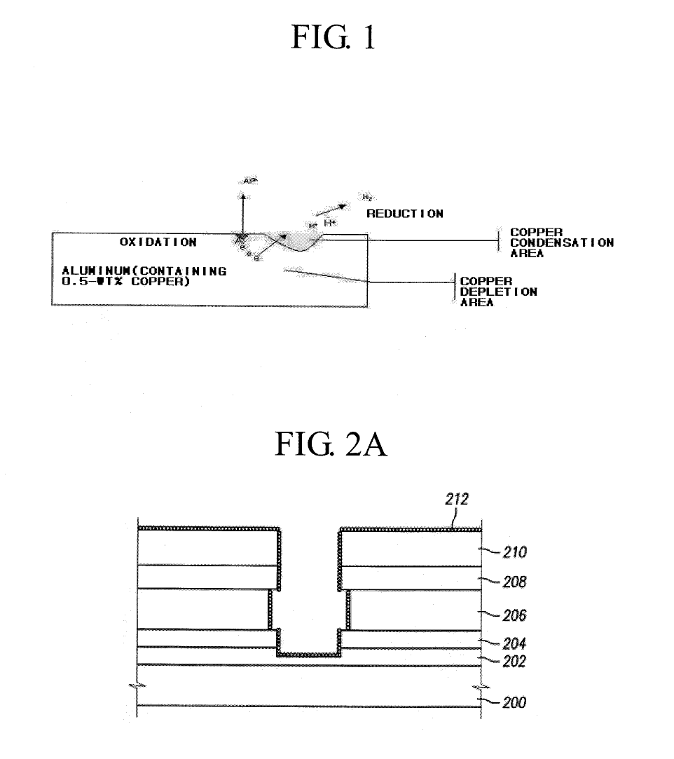

As illustrated in example FIG. 1, aluminum (Al) is oxidized into aluminum ions (Al+3) that may be separated from the metal wiring during removal of a photorsist from a semiconductor substrate. Due to a relative reaction, copper ions (Cu) collect and are converted into solid copper, which separate from the metal wiring. Due to this reaction, metal attack occurs in the metal wiring at a location where copper ions (Cu) collect.

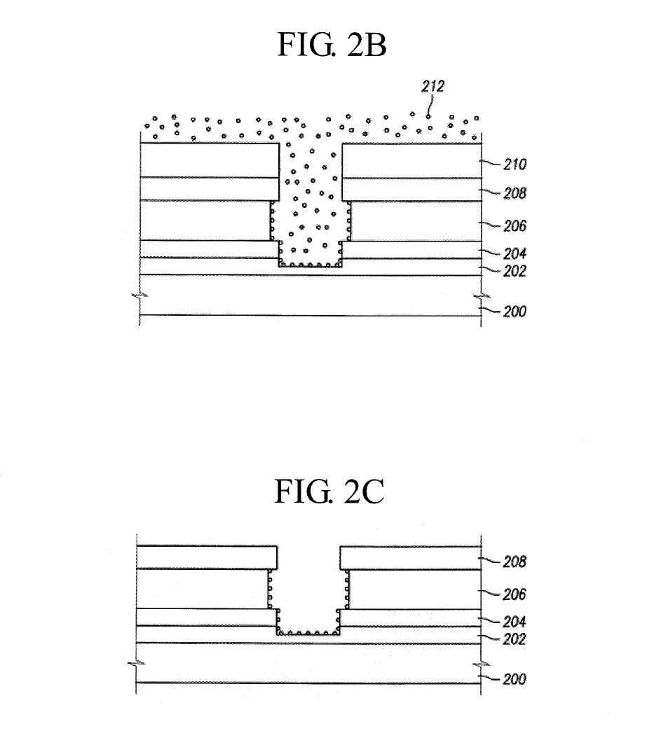

As illustrated in example FIG. 2A, oxide film layer 202, which functions as a dielectric, is formed on and/or over semiconductor substrate 200 in order to form a metal wiring layer. Barrier metal layer 204 and film layer 206 may be sequentially formed on and/or over oxide film 202. Film layer 206 may be composed of a metal such as aluminum or an aluminum alloy containing 0.1 through 1.0 wt % of copper (Cu). Barrier metal layer 204 may be used to prevent a spark phenomenon in which metal is diffused from metal film layer 206 to semiconductor substrate 200 due to increasing adhesive forces and a subsequent heating process.

Anti-reflection film layer 208 and a photoresist are coated on metal film layer 206. The photoresist is then exposed and developed using a predetermined mask for forming a wiring layer pattern, thereby resulting in photoresist pattern 210. In a main processing chamber, exposed antireflection film layer 208 may be removed using photoresist pattern 210 as a mask, where then metal film 206 is patterned using a dry etching method. The dry etching process may use a compound composed of chlorine (Cl₂), boron chloride (BCl₃), CHF₃, and Argon (Ar). As illustrated in example FIG. 2A, polymer 212 containing water (H₂O) and chlorine (Cl) particles may be formed on the surface of photoresist pattern 210 and the side surfaces of metal film 206.

As illustrated in example FIG. 2B, before performing an in-situ plasma etching process in a photoresist removal chamber, in order to remove photoresist pattern 210 the photoresist removal chamber is held at a high pressure while vapor (H₂O) is sprayed to increase the reaction time of polymer layer 212 containing water and chlorine particles. Accordingly, although a minute variation in the atmosphere of the main chamber or the condition of the photoresist removal chamber occurs, photoresist 210 is prevented from remaining by the increase of the reaction time of polymer 212. The surface reaction of semiconductor substrate 200 is prompted using a high-temperature chuck to remove polymer 212. The chuck, which functions as an electrode, sits in a lower side of the chamber where the wafer is placed thereon. Oxygen (O₂) gas may be supplied to the chamber, and a bias voltage generated from an RF generator is applied to the chuck so that its surface temperature is maintained to a high level. Maintaining a high surface temperature on the chuck causes a surface reaction on the wafer. Maintaining the surface temperature of the chuck at an exceeding level may result in metal film layer 206 becoming adversely affected. Consequently, the temperature of the chuck may be maintained at a temperature range of between approximately 200 to 300 degree C.

As illustrated in example FIG. 2C, photoresist pattern 210 may be removed using a plasma etching process while a photoresist removal gas containing fluorine (F) is simultaneously sprayed in order to cause a reaction between aluminum (Al) and fluorine (F) instead of a reaction between aluminum (Al) and copper (Cu). The injection of fluorine during plasma etching may result in a reduction or otherwise elimination of metal attack. The photoresist removal gas may be composed of H₂O and O₂. In accordance with embodiments, the photoresist removal gas may further include a chemical compound including fluorine (F). The fluorine compound may be composed of CHF₃.

In accordance with embodiments, metal attack is reduced or otherwise eliminated by simultaneously injecting fluorine (F) during the removal of a photoresist in a semiconductor manufacturing process, aluminum (Al) and fluorine (F) may react with each other instead of an alternative reaction between aluminum (Al) and copper (Cu).

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
sequentially depositing an oxide film layer and a metal film layer over a semiconductor substrate;
depositing an anti-reflection film layer and a photoresist over the metal film and patterning the photoresist to form a photoresist pattern;
removing a polymer film from a surface of the photoresist pattern by prompting a surface reaction on the semiconductor substrate using a chuck; and
removing the photoresist pattern using a plasma etching process while simultaneously injecting a photoresist removal gas comprising fluorine over the photoresist pattern.

2. The method of claim 1, wherein the metal film layer comprises an aluminum alloy containing between approximately 0.1 through 1.0 wt % of copper.

3. The method of claim 2, wherein removing the photoresist pattern comprises reacting the aluminum alloy with fluorine.

4. The method of claim 1, wherein the chuck is maintained at a temperature range of between approximately 200 to 300 degree C.

5. The method of claim 1, wherein prior to removing the photoresist pattern a vapor comprising water is sprayed to increase a reaction time of the polymer film.

6. A method comprising:
forming an oxide film layer over a semiconductor substrate;
forming a metal film layer over the oxide film layer;
forming an anti-reflection film layer over the metal film layer;
providing a photoresist over the metal film layer;
forming a photoresist pattern;
patterning the metal film layer;
removing a polymer film from a surface of the photoresist pattern; and
removing the photoresist pattern using a photoresist removal gas comprising a chemical compound having fluorine.

7. The method of claim 6, wherein the metal film layer comprises aluminum.

8. The method of claim 6, wherein the metal film layer comprises an aluminum alloy.

9. The method of claim 8, wherein said aluminum alloy contains approximately 0.1 to 1.0 wt % of copper.

10. The method of claim 6, wherein the photoresist pattern is formed by exposing and developing the photoresist using a predetermined mask.

11. The method of claim 6, wherein the anti-reflection film layer is removed using the photoresist pattern as a mask.

12. The method of claim 6, wherein the metal film layer is patterned using a dry etching method.

13. The method of claim 12, wherein the dry etching method utilizes a compound composed of at least one of Cl₂, BCl₃, CHF₃, and Ar.

14. The method of claim 6, wherein the photoresist pattern is removed using a plasma etching process.

15. The method of claim 6, wherein the photoresist removal gas further comprises H₂O and O₂.

16. The method of claim 6, wherein the chemical compound comprises CHF₃.

17. The method of claim 6, wherein prior to forming a metal film layer a barrier metal layer is formed over the oxide film layer.

18. A method comprising:
forming an oxide film layer over a semiconductor substrate;
forming a metal film layer comprising an aluminum alloy including copper over the oxide film layer;
forming an anti-reflection film layer over the metal film layer;
providing a photoresist over the metal film layer;
forming a photoresist pattern;
patterning the metal film layer;
removing a polymer film from a surface of the photoresist pattern; and
removing the photoresist pattern using a photoresist removal gas that inhibits a reaction of aluminum and copper.

19. The method of claim 18, wherein the photoresist removal gas comprises a chemical compound including fluorine.

20. The method of claim 19, wherein the chemical compound comprises CHF₃.
